(19) United States
(12) Patent Application Publication
(10) Pub. No.: US 2024/0355597 A1
(43) Pub. Date: Oct. 24, 2024

(54) ION BEAM ETCH SYSTEM AND METHOD

(71) Applicant: Lam Research Corporation, Fremont, CA (US)

(72) Inventors: Chih-Yang CHANG, Cupertino, CA (US); Raphael CASAES, Alameda, CA (US); Seokmin YUN, Dublin, CA (US); Shih-Yuan CHENG, Hsinchu City (TW); Chih-Min LIN, San Jose, CA (US); Shuogang HUANG, San Jose, CA (US); Anurag Kumar MISHRA, Fremont, CA (US)

(21) Appl. No.: 18/682,869

(22) PCT Filed: Aug. 19, 2022
(86) PCT No.: PCT/US2022/040873

§ 371 Date: Feb. 9, 2024

Related U.S. Application Data
(60) Provisional application No. 63/236,125, filed on Aug. 23, 2021.

(51) Int. Cl. H01J 37/32; H01L 21/3213

(52) U.S. Cl. CPC H01J 37/32862; H01J 37/32422; H01J 37/3244; H01J 37/32926; H01J 37/32082; H01J 2237/334; H01L 21/32136

(57) ABSTRACT

An apparatus for ion beam etching is provided. An ion extractor separates a plasma source chamber from a process chamber. A gas inlet provides gas to the plasma source chamber. An RF power system provides RF power to the plasma source chamber. A process gas source and cleaning gas mixture source are connected to the gas inlet.

### CROSS-REFERENCE TO RELATED APPLICATION

This application claims the benefit of priority of U.S. Application No. 63/236,125, filed Aug. 23, 2021, which is incorporated herein by reference for all purposes.

### BACKGROUND

The background description provided here is for the purpose of generally presenting the context of the present disclosure. Anything described in this background section, and potentially aspects of the written description, are not expressly or impliedly admitted as prior art with respect to the present application.

The disclosure relates to a method of forming semiconductor devices on a semiconductor wafer. More specifically, the disclosure relates to ion beam etching of semiconductor devices.

In forming semiconductor devices, magnetic random access memory (MRAM) may be formed using a pattern transfer process. Such a pattern transfer process uses an etch process. The MRAM stack contains non-volatile and ferromagnetic materials such as cobalt (Co), iron (Fe), manganese (Mn), nickel (Ni), platinum (Pt), palladium (Pd), and ruthenium (Ru). Ion beam etching (IBE) may be used to etch such materials. Ion beams etching that is able to etch metal containing layers may also etch metal containing components of an ion beam etch system.

### SUMMARY

To achieve the foregoing and in accordance with the purpose of the present disclosure, an apparatus for ion beam etching is provided. An ion extractor separates a plasma source chamber from a process chamber. A gas inlet provides gas to the plasma source chamber. An RF power system provides RF power to the plasma source chamber. A process gas source and cleaning gas mixture source are connected to the gas inlet.

In another manifestation, a method for use in an ion beam etch system is provided. The ion beam etch system is cleaned by providing a cleaning gas mixture from a cleaning gas mixture source into a plasma source chamber at a cleaning gas mixture flow rate and energizing the cleaning gas mixture to form a cleaning plasma in the plasma source chamber, wherein the cleaning plasma cleans the ion beam etch system.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a schematic illustration of an ion beam etch system used in an embodiment.

FIG. 2 is a high level flow chart of an embodiment.

FIGS. 3A-B are schematic enlarged views of part of a plasma chamber.

FIG. 4 is a schematic view of a computer system that may be used in practicing an embodiment.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication. A wafer or substrate used in the semiconductor device industry typically has a diameter of 200 mm, 300 mm, or 450 mm. The following detailed description assumes the present disclosure is implemented on a wafer. However, the present disclosure is not so limited. The workpiece may be of various shapes, sizes, and materials. In addition to semiconductor wafers, other workpieces that may take advantage of the present disclosure include various articles such as printed circuit boards and the like.

During semiconductor wafer processing, features may be etched through a metal containing layer. In the formation of magnetic random access memories (MRAM), a plurality of thin metal layers or films may be sequentially etched to form magnetic tunnel junction stacks.

A magnetic tunnel junction (MTJ) is composed of a thin dielectric barrier layer between two magnetic materials. Electrons pass through the barrier by the process of quantum tunneling. This can serve as a basis for magnetic-based memory, using a spin-transfer torque.

The spin-transfer torque is an effect in which the orientation of a magnetic layer in an MTJ can be modified using a spin-polarized current. Charge carriers (e.g., electrons) have a property known as spin. Spin is a small quantity of angular momentum intrinsic to the carrier. An electrical current is generally unpolarized (50% spin-up and 50% spin-down electrons). By passing a current through a thick magnetic layer (usually called the “fixed layer”), a spin polarized current, with more electrons of either spin can be produced. If this spin-polarized current is directed into a second, thinner magnetic layer (the “free layer”), angular momentum can be transferred to this layer, changing its orientation. This effect can be used to excite oscillations or even flip the orientation of the magnet.

Spin-transfer torque can be used to flip the active elements in magnetic random-access memory. Spin-transfer torque magnetic random-access memory (STT-RAM or STT-MRAM) has the advantages of lower power consumption and better scalability over conventional magnetoresistive random-access memory (MRAM). MRAM uses magnetic fields to flip the active elements.

Spin-Torque Transfer Random Access Memory (STT-RAM) device patterning has been demonstrated via either reactive ion etch followed by ion beam etch (IBE); or by a full inert-gas angular IBE strategy. The Reactive ion etch (RIE) process normally results in a tapered profile and heavy sidewall re-deposition of etch byproducts. Moreover, the chemical damages to MgO layers limit RIE only processes for MRAM patterning.

The IBE technique is developed for MRAM pattern transfer while minimizing MTJ damage caused by reactive species. A common approach is to first implement IBE at normal incidence to shape the MTJ and minimize footing and then remove re-deposition from the initial step by providing a sidewall clean by providing IBE at a grazing incidence. Since IBE relies on the sputter of inert ions, metal containing materials of an IBE system may also be etched creating contaminants in the IBE system. The contaminants may redeposit in the IBE system increasing contaminants during processing, causing an increase in defects.

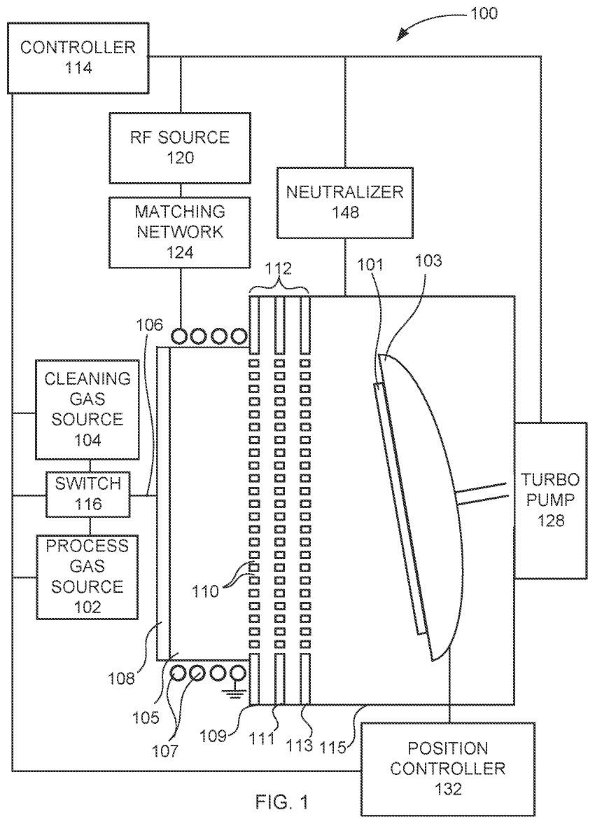

An embodiment provides a method and apparatus for cleaning an IBE system to reduce contaminants and defects. To facilitate understanding, FIG. 1 presents a simplified cross-sectional view of an ion beam etch system 100 for performing ion beam etching according to certain methods. In this example, process wafer 101 rests on the substrate support 103. The substrate support may provide clamping such as mechanical clamping or electrostatic clamping to hold the process wafer 101 on the substrate support 103. The ion beam etch system 100 may be equipped with hardware (not shown) to provide electrical and fluidic connections. The electrical connections may be used to supply electricity to the substrate support 103 or to an electrostatic chuck located on or within the substrate support 103 in some cases, while the fluidic connections may be used to provide fluids used to control the temperature of the process wafer 101 and substrate support 103. The substrate support 103 may be heated by a heater (not shown) and/or cooled by a cooling mechanism (not shown). Any appropriate cooling mechanism may be used. In one example, the cooling mechanism may involve flowing cooling fluids through piping in or adjacent to the substrate support 103. The substrate support 103 may be capable of rotating and tilting at variable speeds and angles. A position controller 132 may be used to control the tilt and rotation of the substrate support 103. The substrate support 103 and process wafer 101 are within a processing chamber 115.

The processing chamber 115 is separated from a plasma source chamber 105 by an ion extractor 112. In this embodiment, the ion extractor 112 comprises a first electrode 109, a second electrode 111, and a third electrode. 113. In this embodiment, the third electrode 113 is grounded. In other embodiments, the ion extractor 112 may be other combinations of electrodes for extracting ions from the plasma source chamber 105. In some embodiments, the ion extractor 112 is able to provide an ion beam from the plasma source chamber 105. The plasma source chamber 105 is surrounded by a coil 107. The coil 107 is electrically connected to a matching network 124 and a radio frequency (RF) source 120. The coil 107, matching network 124, and RF source provide an RF power system for providing RF power to the plasma source chamber 105. A gas inlet 108 is at an end of the plasma source chamber 105. The gas inlet 108 is in fluid connection with a process gas source 102 and a cleaning gas mixture source 104 through at least one manifold 106. The gas inlet 108 may be in one of many different forms. For example, the gas inlet may be a gas distribution plate, a gas diffuser plate, a showerhead, or a gas injector. A turbopump 128 may be in fluid connection to the processing chamber 115 to remove gas from and control the pressure in the processing chamber 115.

In some embodiments, a switch 116 may be in fluid connection between the process gas source 102, the cleaning gas mixture source 104, and the gas inlet 108. The switch 116 may be any device or group of devices that are adapted to switch to provide process gas from the process gas source 102 during wafer processing and cleaning gas mixture from the cleaning gas mixture source 104 during the chamber clean. In some embodiments, the switching prevents process gas from flowing during the wafer chamber cleaning and prevents the cleaning gas mixture from flowing during the wafer processing. In some embodiments, the switch prevents the process gas and the cleaning gas mixture from flowing at the same time and mixing. In some embodiments, the switch 116 comprises one or more of valves, mass flow controllers, and/or other gas flow controllers that provide gas switching without the mixing of the process gas and the cleaning gas mixture.

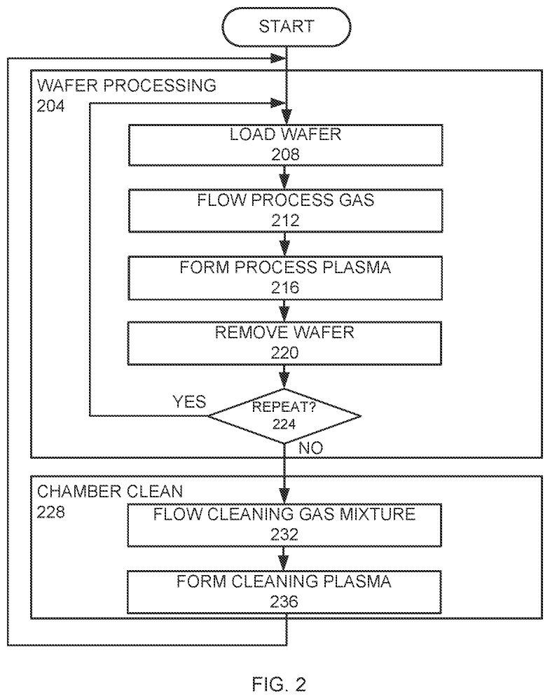

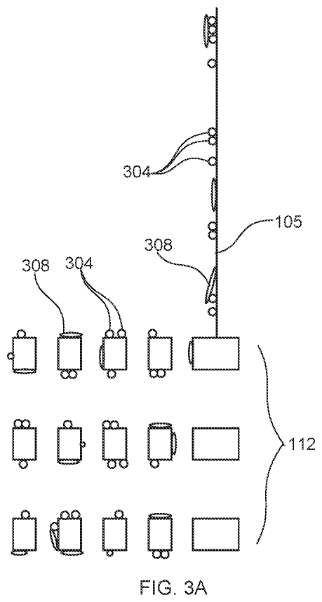

FIG. 2 is a high level flow chart of a method used in an embodiment. A wafer processing step (step 204) is provided by the IBE system 100. Examples of wafer processing steps (step 204) and IBE systems 100 are described in PCT Patent Application serial number PCT/US20/19927 filed on Feb. 26, 2020, entitled “ION BEAM ETCHING WITH SIDEWALL CLEANING”, incorporated by reference for all purposes. In this embodiment, a process wafer 101 is loaded on the substrate support 103 (step 208). A process gas is flowed into the plasma source chamber 105 (step 212) at a process gas flow rate. In some embodiments, the process gas flow rate is between 2 sccm to 500 sccm. In some embodiments, the process gas flow rate is between 7 sccm and 50 sccm. In this embodiment, the process gas consists essentially of argon. In this embodiment, the process gas is xenon and krypton free. One advantage of using argon without xenon or krypton is that argon is much less expensive than xenon or krypton. In other embodiments, argon is the main process gas with 1% to 20% by volume flow xenon or krypton with respect to the total gas flow during the wafer processing step (step 204). So, in this embodiment, the process gas source 102 is an argon gas source. In some implementations, the gas mixture is free of or substantially free of reactive gases. RF power may be applied to coils 107 surrounding the ion beam source chamber to form the process gas into a plasma (step 216). Ions are extracted from the plasma to form an ion beam. A voltage is applied to an ion extractor (e.g., grid) 112 creating a process bias to extract ions to form the ion beam, and the ion beam may be accelerated towards the processing chamber 115. In some embodiments, the process bias is in the range of 10 volts to 5000 volts. In some embodiments, the process bias is in the range of 30 volts to 2000 volts. Controlling the voltage applied to the ion extractor 112 may be used to control an etch rate when performing ion beam etching. A high voltage ion beam may be between about 400 V and about 2000 V for performing a “fast” etch at a high etch rate, and a low voltage ion beam may be between about 30 V and about 400 V for performing a “soft” etch at a low etch rate. Ion beam etching (main etch or separation etch) through at least some of the plurality of MRAM layers, including the tunnel barrier layer, to form the patterned MRAM stacks may be performed at relatively high voltages. Accordingly, the main etch used to etch through the plurality of MRAM layers to form patterned MRAM stacks may be performed at high voltages between about 400 V and about 2000 V. On the other hand, the trim etch or over etch used to clean sidewalls of patterned MRAM stacks may be performed at low voltages between about 30 V and about 400V.

In an embodiment, a positive voltage is applied to the first electrode 109 and a negative voltage is applied to the second electrode 111 so that positive ions are accelerated due to a difference in the potentials between the first electrode 109 and the second electrode 111. The third electrode 113 is grounded. A neutralizer 148 may supply electrons into the processing chamber 115 to neutralize the charge of the ion beam passing through the ion extractor 112, whereas the neutralizer 148 may have its own gas delivery system using an inert gas such as argon or xenon.

Ion beam etching processes are typically run at low pressures. In some embodiments, the pressure may be about 100 mTorr or less, for example about 1 mTorr or less, and in many cases about 0.1 mTorr or less. The low pressure helps minimize undesirable collisions between ions and any gaseous species present in the wafer processing region. In certain cases, a relatively high pressure reactant is delivered in an otherwise low pressure ion processing environment.

In some implementations, etching through at least some of the plurality of MRAM layers may include applying an ion beam to the process wafer 101 having ion energies between about 200 eV and about 10,000 eV. The etch may be performed at high ion energies to efficiently etch materials in the MRAM layers. In some implementations, the etch can be performed in 10 minutes or less, 3 minutes or less, or 1 minute or less. For example, the etch can be performed for between 10 minutes to 10 seconds. In some implementations, the etch can be performed in an ion beam etching apparatus having an ion beam source chamber coupled to a processing chamber.

After the processing of the process wafer is completed, the process wafer 101 may be removed (step 220) and the process may be repeated (step 224) by loading another process wafer 101 onto the substrate support 103. The cycle may be repeated a plurality of times.

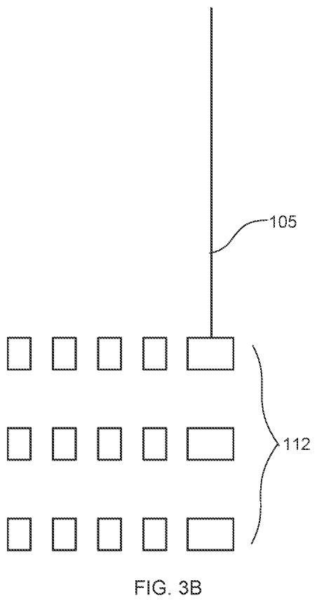

The plasma in the plasma source chamber 105 has a high enough energy to cause metal containing surfaces of the plasma source chamber 105 to be etched and redeposited on parts of the plasma source chamber 105 and the ion extractor 112. Over a plurality of cycles redeposited metal containing material builds up on surfaces of the plasma source chamber 105 and the ion extractor 112. FIG. 3A is an enlarged schematic view of part of the plasma source chamber 105 and ion extractor 112. Metal containing particles 304 and flakes 308 are schematically illustrated as being deposited on the plasma source chamber 105 and ion extractor 112. As the IBE system 100 processes more process wafers 101, the redeposited metal containing materials continue to build. As the redeposited metal containing material increases the number of contaminants deposited during wafer processing increases.

In an embodiment, at about 103 RF hours of use 10 adders (particles of contaminants) were added to an area of the process chamber 115 for each process. An RF hour is defined as an hour of usage while providing RF power. At about 180 RF hours 226 adders were found. Such a significant increase in adders indicates that the redeposited metal containing material significantly increases contamination. In order to reduce such contamination, a chamber clean (step 228) is provided. In some embodiments, the chamber clean is performed without a wafer. In some embodiments, a non-process wafer may be placed on the substrate support 103. A non-process wafer is different than a process wafer in that semiconductor devices are not formed on the non-process wafer and the non-process wafer is discarded after use. A cleaning gas mixture is flowed into the plasma source chamber 105 (step 232). In some embodiments, the cleaning gas mixture consists essentially of a cleaning gas of xenon or krypton. In some embodiments, the cleaning gas mixture consists essentially of a carrier gas, such as nitrogen N₂, and a cleaning gas of at least one of xenon or krypton. In some implementations, the cleaning gas mixture is free of or substantially free of reactive gases and is argon free. In an embodiment, the cleaning gas is krypton, so that the cleaning gas mixture source 104 is a krypton gas source. In other embodiments, the cleaning gas is xenon, so that the cleaning gas mixture source 104 is a xenon gas source and in some embodiments also is a nitrogen gas source. In some embodiments, the cleaning gas flow rate is in the range of 2 sccm to 500 sccm. In some embodiments, the cleaning gas flow rate is in the range of 2 sccm to 50 sccm. In some embodiments, the cleaning gas mixture source 104 further comprises a carrier gas source, such as a nitrogen gas source, in addition to a xenon gas source and/or a krypton gas source. In some embodiments, the carrier gas has a flow rate in the range of 0 sccm to 10,000 sccm. At high flow rates, it is easier to control pressure instead of flow rate. A pressure in the range of 0.1 milliTorr (mT) to 520 Torr is provided in some embodiments. In some embodiments, the cleaning gas mixture has a cleaning gas mixture flow rate that is between 20 to 50 times the process gas flow rate. In some embodiments, the cleaning gas mixture has a flow rate in the range of 40 sccm and 10,000 sccm. In some embodiments, the cleaning gas mixture has a flow rate in the range of 140 sccm to 1000 sccm. RF power may be applied to coils 107 surrounding the ion beam source chamber to form the cleaning gas mixture into a plasma (step 236). A high voltage ion beam may be between about 10 V and about 5000 V for performing a clean. In this embodiment, the voltage is provided by applying a positive voltage to the first electrode 109 and a negative voltage to the second electrode 111, creating a cleaning bias, so that positive ions are accelerated due to a difference in the potentials between the first electrode 109 and the second electrode 111. In other embodiments, during the cleaning, a cleaning bias voltage in the range of 30 V to 2000 V is applied. In some embodiments, the cleaning plasma is maintained for a time period of between 5 minutes to 40 minutes. In some embodiments, the use of a cleaning gas without a carrier gas would have insufficient kinetic energy to provide sufficient cleaning. Providing a carrier gas in order to provide a cleaning gas mixture with a flow rate of 20 to 50 times the flow rate of the process gas provides sufficient kinetic energy for cleaning. In some embodiments, pulsing the cleaning gas, carrier gas, or cleaning gas mixture provides some turbulence within the chamber that increases the efficacy of particle removal. In some embodiments, the pulsing is at a frequency of no more than 50 Hz. In some embodiments, the process gas of argon is not flowed simultaneously with and is not mixed with a cleaning gas of at least one of krypton or xenon.

FIG. 3B is an enlarged schematic view of part of the plasma source chamber 105 and ion extractor 112 after the chamber clean (step 228). Metal containing particles 304 and flakes 308 (shown in FIG. 3A) have been cleaned from the plasma source chamber 105 and ion extractor 112. It has been found that the chamber clean (step 228) has removed some of the metal containing residue. In addition, the surface resistance of the gas inlet 108 is measured after use of more than 100 RF hours and then measured again after the chamber clean (step 228). The surface resistance after use of more than 100 RF hours was measured to be in the range of 1 to 20 thousand ohms. This low resistance indicates that metal containing material has been redeposited on the gas inlet 108. After the chamber clean (step 228) the surface resistance was measured to be in the range of 10 to 20 million ohms. An increase of surface resistance on the order of a thousand times indicates that redeposited metal containing material has been removed.

In some experiments, an ion beam etch system 100 that had been used to the point of providing 359 adders was cleaned using a Xe cleaning gas and a 400 volt cleaning bias reduced the number of adders to 22 adders during processing. In other experiments, the number of adders was reduced to below 10. These examples show that the chamber clean (step 228) is useful in reducing the number of defects by reducing the number of adders for each process. It has been found by experiment that using argon as the cleaning gas does not provide a sufficient clean. It is believed that higher mass inert gases improve the cleaning process. In some embodiments, more than 5 minutes of cleaning is needed. For example, cleaning for about 20 minutes provides desired cleaning. In some embodiments, the chamber clean (step 228) is performed for a time in the range of 5 minutes to 40 minutes. In other embodiments, the cleaning plasma is maintained for a period of from 1 minute to 60 minutes. In other embodiments, the cleaning plasma is maintained for a period from 20 minutes to 40 minutes.

In some embodiments, the number of adders is periodically measured. When the number of adders increases beyond a threshold or by a certain percentage, a determination is made to not process another wafer (step 224), but instead, perform a chamber clean (step 228). In other embodiments, a recipe may specify that a chamber clean (step 228) is performed after a specified number of wafers are processed or after a specified number of RF hours.

In various embodiments, it has been found that the metal containing materials may comprise aluminum, silicon, copper, iron, molybdenum, and nickel. Some of the metal containing materials may be metal oxides. The chamber clean (step 228) has been found to remove metal containing various combinations of aluminum, silicon, copper, iron, molybdenum, and nickel. The chamber clean (step 228) has been found to remove various metal oxides. In other embodiments, the metal containing materials may comprise chromium, iridium, ruthenium, manganese, and platinum. In other embodiments, the metal containing materials may comprise other transition metals in the 1st, 2nd, and 3rd rows (e.g., Group IV transition metals, Group V transition metals, and Group VI transition metals), including metals such as copper.

In the prior art, a wet clean is used to remove redeposited metal containing materials. In order to provide the wet clean, the chamber is taken apart and the parts are separately wet cleaned before the chamber is reassembled. In the alternative, some of the parts may be replaced with new parts instead of the used parts being cleaned. Cleaning may be needed every 180 RF hours. Disassembly, wet cleaning, and reassembling of the chamber result in a longer downtime than the ion beam cleaning used in an embodiment. The replacement of an old part for a new part increases the cost of ownership. Therefore, the ion beam cleaning used in an embodiment reduces downtime and lowers the cost of ownership.

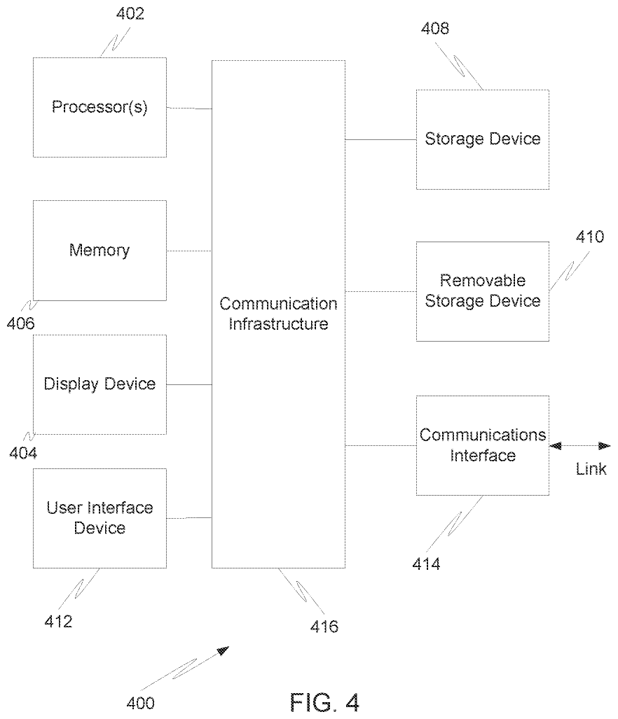

FIG. 4 is a high level block diagram showing a computer system 400. The computer system 400 is suitable for implementing a controller 114 used in embodiments. The computer system 400 may have many physical forms ranging from an integrated circuit, a printed circuit board, and a small handheld device up to a huge supercomputer. The computer system 400 includes one or more processors 402, and further can include an electronic display device 404 (for displaying graphics, text, and other data), a main memory 406 (e.g., random access memory (RAM)), a storage device 408 (e.g., hard disk drive), removable storage device 410 (e.g., optical disk drive), user interface devices 412 (e.g., keyboards, touch screens, keypads, mice or other pointing devices, etc.), and a communications interface 414 (e.g., wireless network interface). The communications interface 414 allows software and data to be transferred between the computer system 400 and external devices via a link. The system may also include a communications infrastructure 416 (e.g., a communications bus, cross-over bar, or network) to which the aforementioned devices/modules are connected.

Information transferred via communications interface 414 may be in the form of signals such as electronic, electromagnetic, optical, or other signals capable of being received by communications interface 414, via a communications link that carries signals and may be implemented using wire or cable, fiber optics, a phone line, a cellular phone link, a radio frequency link, and/or other communications channels. With such a communications interface 414, it is contemplated that the one or more processors 402 might receive information from a network, or might output information to the network in the course of performing the above-described method steps. Furthermore, method embodiments may execute solely upon the processors or may execute over a network such as the Internet, in conjunction with remote processors that share a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory and shall not be construed to cover transitory subject matter, such as carrier waves or signals. Examples of computer readable code include machine code, such as produced by a compiler, and files containing higher level code that are executed by a computer using an interpreter. Computer readable media may also be computer code transmitted by a computer data signal from a processor.

In some embodiments, the computer readable media may comprise computer readable code for processing at least one wafer and computer readable code for cleaning the plasma source chamber and the grid system. The computer readable code for processing at least one wafer may comprise computer readable code for loading at least one wafer into the process chamber, computer readable code for providing a process gas from the process gas source into the plasma source chamber, computer readable code for providing at least one bias to the grid system, computer readable code for energizing the process gas to form a process plasma in the plasma source chamber, wherein the grid system passes ions from the plasma source chamber to the process chamber, where the ions are converted to energetic neutrals to process the at least one wafer in the process chamber, and computer readable code for removing the at least one wafer from the process chamber. The computer readable code for cleaning the plasma source chamber and the grid system may comprise computer readable code for providing a cleaning gas mixture from the cleaning gas mixture source into the plasma source chamber, and computer readable code for energizing the cleaning gas mixture to form a cleaning plasma in the plasma source chamber, wherein the cleaning plasma cleans the plasma source chamber and the grid system.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

What is claimed is:

1. An apparatus for ion beam etching, comprising:
a plasma source chamber;
a process chamber;
an ion extractor separating the plasma source chamber from the process chamber;
a gas inlet for providing gas to the plasma source chamber;
an RF power system for providing RF power to the plasma source chamber;
a process gas source connected to the gas inlet; and
a cleaning gas mixture source connected to the gas inlet.

2. The apparatus, as recited in claim 1, further comprising a controller controllably connected to the process gas source and the cleaning gas mixture source.

3. The apparatus of claim 2, wherein the controller comprises:
at least one processor; and
computer readable media, comprising:
computer readable code for processing at least one wafer, comprising:
computer readable code for loading at least one wafer into the process chamber;
computer readable code for providing a process gas at a process gas flow rate from the process gas source into the plasma source chamber;
computer readable code for providing at least one process bias to the ion extractor;
computer readable code for energizing the process gas to form a process plasma in the plasma source chamber, wherein the ion extractor passes energetic neutrals from the plasma source chamber to the process chamber to process the at least one wafer in the process chamber; and
computer readable code for removing the wafer from the process chamber;
computer readable code for cleaning the plasma source chamber and the ion extractor, comprising:
computer readable code for providing a cleaning gas mixture from the cleaning gas mixture source into the plasma source chamber at a cleaning gas mixture flow rate; and
computer readable code for energizing the cleaning gas mixture to form a cleaning plasma in the plasma source chamber, wherein the cleaning plasma cleans the plasma source chamber and the ion extractor.

4. The apparatus, as recited in claim 3, wherein the computer readable code for cleaning the plasma source chamber and the ion extractor, further comprises computer readable code for applying a cleaning bias through the ion extractor.

5. The apparatus, as recited in claim 4, wherein computer readable code for providing the cleaning gas mixture provides the cleaning gas mixture at a flow rate that is at least 20 times the process gas flow rate.

6. The apparatus, as recited in claim 3, wherein computer readable code for providing the cleaning gas mixture provides the cleaning gas mixture at a flow rate that is at least 20 times the process gas flow rate.

7. The apparatus, as recited in claim 1, wherein the cleaning gas mixture source comprises at least one of a krypton gas source or a xenon gas source and wherein the process gas source comprises an argon gas source.

8. The apparatus, as recited in claim 7, wherein the cleaning gas mixture source further comprises a nitrogen gas source.

9. A method for use in an ion beam etch system, comprising:
cleaning the ion beam etch system, comprising:
providing a cleaning gas mixture from a cleaning gas mixture source into a plasma source chamber at a cleaning gas mixture flow rate; and
energizing the cleaning gas mixture to form a cleaning plasma in the plasma source chamber, wherein the cleaning plasma cleans the ion beam etch system.

10. The method, as recited in claim 9, wherein the cleaning gas mixture comprises at least one of krypton and xenon.

11. The method, as recited in claim 10, wherein the cleaning gas mixture further comprises nitrogen.

12. The method, as recited in claim 9, further comprising:
processing at least one wafer, comprising:
loading at least one wafer into a process chamber;
providing a process gas from a process gas source at a process gas flow rate into the plasma source chamber;
providing at least one bias at a process bias to an ion extractor separating the plasma source chamber from the process chamber;
energizing the process gas to form a process plasma in the plasma source chamber, wherein the ion extractor passes ions from the plasma source chamber to the process chamber to process the at least one wafer in the process chamber; and
removing the at least one wafer from the process chamber.

13. The method, as recited in claim 12, wherein the cleaning plasma cleans the plasma source chamber and the ion extractor.

14. The method, as recited in claim 13, wherein the cleaning gas mixture comprises at least one of krypton and xenon and wherein the process gas comprises argon.

15. The method, as recited in claim 14, wherein the cleaning gas mixture further comprises nitrogen.

16. The method, as recited in claim 14, wherein the argon is not flowed simultaneously with the at least one of krypton and xenon with argon.

17. The method, as recited in claim 13, wherein the cleaning gas mixture flow rate is at least 20 times the process gas flow rate.
